(19) United States
(12) Patent Application Publication
(10) Pub. No.: US 2012/0132984 A1
(43) Pub. Date: May 31, 2012

(54) SEMICONDUCTOR DEVICE AND METHOD OF MANUFACTURING THE SAME AS WELL AS SEMICONDUCTOR MEMORY AND METHOD OF MANUFACTURING THE SAME

(75) Inventors: Michihiko Mifuji, Kyoto-shi (JP); Yuichi Nakao, Kyoto-shi (JP); Toshikazu Mizukoshi, Kyoto-shi (JP); Bungo Tanaka, Kyoto-shi (JP); Taku Shibaguchi, Kyoto-shi (JP); Gentaro Morikawa, Kyoto-shi (JP)

(73) Assignee: ROHM CO., LTD., Kyoto (JP)

(21) Appl. No.: 13/364,893

(22) Filed: Feb. 2, 2012

(30) Foreign Application Priority Data
Sep. 9, 2010 (JP) 2010-202369
Sep. 9, 2010 (JP) 2010-202370
Sep. 9, 2010 (JP) 2010-202371
Sep. 9, 2010 (JP) 2010-202372

(51) Int. Cl. H01L 29/792; H01L 21/768; H01L 29/78; H01L 27/04; H01L 21/28; H01L 23/532; H01L 21/76

(52) U.S. Cl. 257/324; 257/751; 438/643; 438/401; 438/400; 257/499; 438/591; 257/288; 257/E29.255; 257/E29.309; 257/E27.01; 257/E23.157; 257/E21.19; 257/E21.584; 257/E21.54

(57) ABSTRACT

A contact plug 40 electrically connected to an impurity diffusion region between sidewalls of an adjacent pair of memory cells 1 is provided to pass through an interlayer dielectric film 18. A side wall of a contact hole 41 is covered with a sealing film 42 denser than the interlayer dielectric film 18. The contact plug 40 includes a barrier metal film 43 formed to cover a surface of the sealing film 42 and a bottom surface portion of the contact hole 41 and a metal plug 44 embedded in the contact hole 41 in a state surrounded by the barrier metal film 43.

### BACKGROUND OF THE INVENTION

1. Field of the Invention

The present invention relates to a semiconductor device and a method of manufacturing the same as well as a semiconductor memory and a method of manufacturing the same.

2. Description of Related Art

In a semiconductor device such as a semiconductor memory including a plurality of gates formed at a small pitch (not more than 250 nm, for example), an interlayer dielectric film is embedded between the gates, and a contact plug is formed to pass through the interlayer dielectric film (refer to Japanese Unexamined Patent Publication No. 2010-80771, for example). In such a semiconductor device, BPSG (Boron Phosphorous Silicate Glass) having excellent embeddability, for example, is embedded between the gates as the interlayer dielectric film. BPSG can fill up a space between the gates formed at a small interval by entering the space.

The contact plug electrically connects a source of a memory cell transistor and an upper wiring layer with each other, for example. The contact plug is formed as follows, for example: First, a contact hole passing through the interlayer dielectric film is formed. Then, a barrier metal film is formed to cover a side surface and a bottom surface portion of the contact hole. Then, a metal plug is embedded in the contact hole in a state surrounded by the barrier metal film. The metal plug is made of tungsten, for example. The barrier metal film is formed by a multilayer film of TiN and Ti, for example.

### SUMMARY OF THE INVENTION

When the contact plug is formed in the interlayer dielectric film, the material (tungsten, for example) for the metal plug may bleed into the interlayer dielectric film through the barrier metal film if adhesion between the barrier metal film and the interlayer dielectric film is inferior and a through-hole is formed in the barrier metal film. In particular, the interlayer dielectric film exhibits a rough surface state when the same is made of BPSG, and hence the adhesion between the barrier metal film and the interlayer dielectric film is inferior, and a through-hole may be formed in the barrier metal film. Therefore, the material for the metal plug may bleed into the interlayer dielectric film through the barrier metal film. Thus, the contact plug and another contact plug may be short-circuited, for example.

An object of the present invention is to provide a semiconductor device capable of preventing the material for a metal plug embedded in a contact hole from bleeding into an interlayer dielectric film and a method of manufacturing the same.

In a case of manufacturing a semiconductor memory, alignment of a mask employed for patterning a gate electrode is performed through an alignment mark formed on an alignment mark region on a semiconductor substrate. The alignment mark is formed as follows, for example: In a step of forming an element isolation trench for isolating an active region in a memory cell region on the semiconductor substrate, an alignment trench is simultaneously formed in the alignment mark region on the semiconductor substrate. Then, insulating films are embedded in the element isolation trench and the alignment trench. Thereafter the insulating film in the alignment trench is entirely removed (refer to Japanese Unexamined Patent Publication No. 2003-158179, for example).

In order to reliably detect a write state (a charge retention state) of a memory cell, a memory cell current is effectively increased. The memory cell current can be increased by employing a fin transistor. The fin transistor has a structure of attaining enlargement of a gate width by employing not only an upper surface but also a side surface of a striped active region as channels. More specifically, the insulating film in the element isolation trench is dug down to expose a portion (an upper portion) of the side surface of the active region in the aforementioned semiconductor memory. Then, a gate electrode is formed to be opposed to the upper surface and the side surface of the active region. Thus, the gate width can be increased, whereby the memory cell current can be increased.

The inventor has conducted a study on application of the aforementioned prior art to a semiconductor memory having a memory cell transistor formed by a fin transistor. In this case, an alignment trench is simultaneously formed in an alignment mark region on a semiconductor substrate in a step of forming an element isolation trench. Then, insulating films are embedded in the element isolation trench and the alignment trench. Further, the insulating film in the element isolation trench is dug down, in order to prepare a fin transistor. On the other hand, the insulating film in the alignment trench is entirely removed.

When such manufacturing steps are employed, however, a photomask used for forming a resist pattern for digging down the insulating film in the element isolation trench and that used for forming a resist pattern for entirely removing the insulating film from the alignment trench must be individually prepared. Therefore, the number of photomasks is increased, and the number of steps is also increased in response thereto.

Another object of the present invention is to provide a semiconductor memory having a structure allowing simultaneous etching of an insulating film in an element isolation trench and an insulating film in an alignment trench through one mask and a method of manufacturing the same.

A device in which a plurality of element isolation portions and an active region held between the element isolation portions are formed on a surface layer portion of a silicon substrate with a semiconductor element such as a memory cell formed on the active region is known as a semiconductor device (refer to Japanese Unexamined Patent Publication No. 2010-87134, for example).

The element isolation portions are generally formed as follows: First, a pad oxide film is formed on the silicon substrate. Then, a nitride film is formed on the pad oxide film. Then, the nitride film and the pad oxide film are selectively removed by etching, while leaving portions corresponding to the active region. Then, the silicon substrate is etched through a hard mask constituted of the nitride film and the pad oxide film, thereby forming an element isolation trench in the silicon substrate. Then, a liner oxide film is formed on an inner surface of the element isolation trench. Then, heat treatment is performed in a nitrogen atmosphere, in order to recover the active region from crystal damage resulting from the etching for forming the element isolation trench. More specifically, the heat treatment is performed in order to cure crystal defects formed on edge portions of the active region due to stress resulting from the nitride film constituting the hard mask. Thereafter an insulator is deposited in the element isolation trench. The liner oxide film is formed in order to prevent a silicon surface from nitriding in the heat treatment.

In the aforementioned semiconductor device, a gate width is enlarged if a large area can be ensured for an upper portion of the active region, whereby a cell current can be increased. In order to ensure a large area for the upper portion of the active region, the width of the element isolation trench may simply be reduced. If the width of the element isolation trench is reduce, however, embeddability of the insulator in the element isolation trench is deteriorated, and a void may be formed.

This problem can be solved by reducing the thickness of the liner oxide film. If the thickness of the liner oxide film is reduced, however, a silicon surface of a side wall of the element isolation trench is nitrided in the heat treatment in the nitrogen atmosphere performed after the formation of the liner oxide film. In other words, a nitride film made of SiN is formed on the silicon surface. The nitride film has higher stress than an oxide film, andhence high stress is applied to an Si/SiN interface due to temperature change in temperature reduction after the heat treatment, and dislocations are formed in the active region. Therefore, crystallinity of the active region is deteriorated, to deteriorate characteristics of the semiconductor device.

Still another object of the present invention is to provide a semiconductor device allowing reduction of the width of an element isolation trench without deteriorating crystallinity of a semiconductor substrate and a method of manufacturing the same.

FIGS. 13A and 13B are sectional views schematically showing partial steps of manufacturing a semiconductor memory. FIG. 13A shows a state where two gate portions 103 are formed on a silicon substrate 102 at an interval. Each gate portion 103 includes a gate oxide film 106 formed on the silicon substrate 102, a gate electrode 107 formed on the gate oxide film 106, and an insulating film 108 formed on the gate electrode 107. The gate oxide film 106 is made of SiO₂. The gate electrode 107 includes a polysilicon layer 109 formed on the gate oxide film 106 and a tungsten silicide layer 110 stacked on the polysilicon layer 109. In other words, the gate electrode 107 has the so-called polycide structure. The insulating film 108 is made of SiN, for example.

When the gate portions 103 are formed, an impurity for forming an LDD (Lightly Doped Drain) structure is implanted into regions of a surface layer portion of the silicon substrate 102 holding a channel region immediately under each gate portion 103 therebetween, as shown in FIG. 13B. Thus, LDD portions 104 are formed on the surface layer portion of the silicon substrate 102. Thereafter sidewalls 112a and 112b functioning as charge storage portions are formed on both side walls of each gate portion 103.

Each of the sidewalls 112a and 112b has a three-layer structure of an inner oxide film formed on a side wall surface of the gate portion 103, a nitride film formed on a surface of the inner oxide film and an outer oxide film formed on a surface of the nitride film. The inner oxide film is formed by thermal oxidation. The nitride film is formed by low pressure CVD (Chemical Vapor Deposition). The tungsten silicide layer 110 of each gate portion 103 expands in the formation of the inner oxide film by thermal oxidation and the formation of the outer oxide film by low pressure CVD, to protrude outward beyond the polysilicon layer 109.

Thereafter an impurity for forming drain regions and a source region is ion-implanted into portions of the surface layer portion of the silicon substrate 102 between the sidewalls 112a and 112b. Thus, drain regions 105a and a source region 105b are formed, and the LDD portions 104 are separated into two types of regions 104a and 104b closer to the drain regions 104a and to the source region 105b respectively. Then, an interlayer dielectric film 118 is formed on surfaces of the silicon substrate 102, the gate portions 103 and the sidewalls 112a and 112b.

Before the formation of the interlayer dielectric film 118, the tungsten silicide layer 110 of each gate portion 103 has a shape projecting outward beyond the polysilicon layer 109. Therefore, the interval between the sidewalls of the adjacent gate portions 103 is locally narrowed. When the interlayer dielectric film 118 is formed, therefore, a void 119 is easily caused due to defective embedding of the interlayer dielectric film 118. Further, impurity ions are hard to implant into portions of the surface layer portion of the silicon substrate 102 in the vicinity of the sidewalls 112a and 112b in the impurity implantation for forming the drain regions 105a and the source region 105b. Therefore, a driving current for or an operating speed of the semiconductor memory may be reduced. In other words, characteristics cannot be easily implemented as designed.

A further object of the present invention is to provide a semiconductor device capable of preventing defective embedding when an interlayer dielectric film is embedded between sidewalls and a method of manufacturing the same.

A first semiconductor device according to the present invention includes an interlayer dielectric film, a sealing film, formed to cover a side wall of a contact hole formed to pass through the interlayer dielectric film, denser than the interlayer dielectric film, a barrier metal film formed to cover a surface of the sealing film and a bottom surface portion of the contact hole, and a metal plug embedded in the contact hole in a state surrounded by the barrier metal film.

In the first semiconductor device, the sealing film denser than the interlayer dielectric film is formed to cover the side wall of the contact hole formed to pass through the interlayer dielectric film. Therefore, the sealing film has a smooth surface state, whereby the barrier metal film exhibits excellent adhesion, and formation of an unintended through-hole (out of design) can be suppressed or prevented. Thus, the material for the metal plug embedded in the contact hole can be inhibited or prevented from bleeding into the interlayer dielectric film.

According to one embodiment of the present invention, the sealing film is formed by a nitride film.

According to one embodiment of the present invention, the interlayer dielectric film is made of BPSG.

According to one embodiment of the present invention, the metal plug is made of tungsten.

According to one embodiment of the present invention, the semiconductor device further includes a plurality of gate portions formed at a pitch of not more than 250 nm, and the contact hole is formed between adjacent ones of the gate portions. In order to embed the interlayer dielectric film between the gate portions formed at such a small pitch with excellent embeddability, BPSG is preferably employed as the material for the interlayer dielectric film. A BPSG film is rough in film quality, and has a rough surface state in response to thereto. Therefore, the sealing film (an SiN film, for example) denser than the BPSG film is so formed on the side wall of the contact hole that reliability can be simultaneously ensured while attaining functionalization and/or downsizing of the semiconductor device by forming the gate portions in high density.

According to one embodiment of the present invention, each of the gate portions has a multilayer structure of a plurality of layers.

A first method of manufacturing a semiconductor device according to the present invention includes the steps of forming an interlayer dielectric film on a semiconductor substrate, forming a contact hole passing through the interlayer dielectric film, forming a sealing film denser than the interlayer dielectric film to cover a side wall of the contact hole, forming a barrier metal film covering a surface of the sealing film and a bottom surface portion of the contact hole, and forming a metal plug embedded in the contact hole in a state surrounded by the barrier metal film with source gas having corrosiveness on the interlayer dielectric film.

According to the first method of manufacturing a semiconductor device, the sealing film denser than the interlayer dielectric film is formed to cover the side wall of the contact hole before the formation of the barrier metal film. Then, the metal plug embedded in the contact hole in the state surrounded by the barrier metal film is formed with the source gas having corrosiveness on the interlayer dielectric film after the formation of the barrier metal film. When the metal plug is formed, therefore, the sealing film can prevent the source gas from reaching the interlayer dielectric film. Thus, the source gas can be prevented from corroding the interlayer dielectric film, or the material for the metal plug can be prevented from bleeding into the interlayer dielectric film.

In the method of manufacturing a semiconductor device according to one embodiment of the present invention, the sealing film is formed by a nitride film.

In the method of manufacturing a semiconductor device according to one embodiment of the present invention, the interlayer dielectric film is formed by an oxide film, and the step of forming the metal plug includes a step of forming the metal plug with source gas containing fluorine.

A semiconductor memory according to the present invention includes a semiconductor substrate having a memory cell region provided with an element isolation trench isolating an active region and an alignment mark region provided with an alignment trench for mask alignment. The semiconductor memory further includes a first insulating film, embedded up to an intermediate portion of the element isolation trench in a depth direction so that the active region between the element isolation trench and another element isolation trench protrudes, having a surface on a position deeper than the semiconductor substrate, and a second insulating film embedded up to an intermediate portion of the alignment trench in a depth direction.

The first insulating film in the element isolation trench can be formed by embedding an insulating film in the element isolation trench and thereafter digging down the insulating film by etching. Similarly, the second insulating film in the alignment trench can be formed by embedding an insulating film in the alignment trench and thereafter digging down the insulating filmby etching. Therefore, the insulating films in the element isolation trench and the alignment trench can be simultaneously etched through one mask. Thus, the numbers of masks and manufacturing steps can be reduced.

According to one embodiment of the present invention, the first insulating film and the second insulating film have equal thicknesses. Such a structure can be formed by forming an insulating film embedded in both of the element isolation trench and the alignment trench, digging down the insulating film by etching, and partially leaving the insulating film in the element isolation trench and the alignment trench respectively, for example. For example, the depths of the element isolation trench and the alignment trench from the surface of the semiconductor substrate may be equal to each other, and the first insulating film and the second insulating film may have equal thicknesses. In this case, the depth (the quantity of digging) from the surface of the semiconductor substrate to the surface of the first insulating film and the depth (the quantity of digging) from the surface of the semiconductor substrate to the surface of the second insulating film are equal to each other.

The semiconductor memory according to one embodiment of the present invention further includes a metal film, formed on the semiconductor substrate, having a planar surface in the memory cell region and having a step portion corresponding to the alignment trench in the alignment mark region. For example, the width of the element isolation trench is smaller than the width of the alignment trench. When a metal film covering the surfaces of the semiconductor substrate, the first insulating film and the second insulating film is formed in this case, the surface of the metal film is planarized in the memory cell region, while an observable step portion is formed on the surface of the metal film on the alignment trench.

The semiconductor memory according to one embodiment of the present invention further includes a gate electrode arranged on the semiconductor substrate to traverse the active region between the element isolation trench and another element isolation trench, a first charge storage portion arranged on a first side wall portion of the gate electrode to be opposed to the active region, and a second charge storage portion arranged on a second side wall portion of the gate electrode opposite to the first side wall portion to be opposed to the active region. The active region protrudes from the first insulating film in the element isolation trench, whereby the gate electrode is opposed not only to an upper surface of the active region, but also to a side surface portion thereof when arranged to traverse the active region between the element isolation trench and another element isolation trench. In other words, a fin transistor structure is obtained. In order to perform a read operation for detecting charge storage states of the first and second charge storage portions formed on the first and second side wall portions of the gate electrode, a memory cell current is preferably increased. A current in the read operation can be increased by employing the fin transistor structure and increasing a gate width, whereby the read operation can be reliably performed. When such a fin transistor structure is employed, the number of masks can be reduced and the number of manufacturing steps can also be reduced in response thereto by leaving the second insulating film in the alignment trench.

A method of manufacturing a semiconductor memory according to the present invention includes the steps of forming an element isolation trench in a memory cell region of a semiconductor substrate, forming an alignment trench in an alignment mark region of the semiconductor substrate, embedding a first insulating film in the element isolation trench, embedding a second insulating film in the alignment trench, and digging down the first insulating film up to an intermediate portion of the element isolation trench in a depth direction and digging down the second insulating film up to an intermediate portion of the alignment trench in a depth direction by simultaneously etching the first insulating film and the second insulating film. According to the method of manufacturing a semiconductor memory, the first insulating film embedded in the element isolation trench and the second insulating film embedded in the alignment trench can be simultaneously etched through one mask. Thus, the numbers of masks and manufacturing steps can be reduced.

A second method of manufacturing a semiconductor device according to the present invention includes a step of forming an element isolation trench for isolating an active region in a semiconductor substrate, a step of forming a liner oxide film on an inner surface of the element isolation trench by thermal oxidation, a heat treatment step of heat-treating the semiconductor substrate by arranging the semiconductor substrate in a nitrogen atmosphere after the formation of the liner oxide film, a step of reducing the thickness of the liner oxide film, and a step of embedding an insulator in the element isolation trench.

According to the method of manufacturing a semiconductor device, the heat treatment is performed in a state where a thick liner oxide film is formed on the inner surface of the element isolation trench. The thickness of the liner oxide film is thereafter reduced, and hence the liner oxide film may simply have a thickness sufficient for preventing the inner surface of the element isolation trench from nitriding at the time of the heat treatment. Thus, crystallinity of the active region can be prevented from deterioration. The thickness of the liner oxide film is reduced after the heat treatment, whereby the width of the element isolation trench (the width of a trench space partitioned by the liner oxide film) is increased. The insulator is embedded in the element isolation trench increased in width. Therefore, formation of a void in the insulator can be suppressed or prevented.

According to the method of manufacturing a semiconductor device, the final thickness of the liner oxide film can be reduced without deteriorating crystallinity of the semiconductor substrate. Therefore, the width of the element isolation trench (before the formation of the liner oxide film) can be reduced without deteriorating the crystallinity of the semiconductor substrate.

According to one embodiment of the present invention, the step of reducing the thickness of the liner oxide film includes a step of etching a portion of not less than half an initial thickness (in advance of the step of reducing the thickness of the liner oxide film) of the liner oxide film.

According to one embodiment of the present invention, the heat treatment step includes heat treatment at a temperature higher than a temperature in the thermal oxidation for forming the liner oxide film.

According to one embodiment of the present invention, the heat treatment step includes a heat treatment step at a temperature of 1100° C. to 1200° C.

According to one embodiment of the present invention, the initial thickness (in advance of the step of reducing the thickness of the liner oxide film) of the liner oxide film is not less than 8 nm.

A second semiconductor device according to the present invention includes a semiconductor substrate provided with an element isolation trench isolating an active region, a liner oxide film having a thickness of not more than 50 Å formed on an inner surface of the element isolation trench, and an insulator embedded in the element isolation trench. In the semiconductor device, the thickness of the liner oxide film formed on the inner surface of the element isolation trench is small, whereby the width of an upper surface portion of the active region can be increased by reducing the width of the element isolation trench.

A third method of manufacturing a semiconductor device according to the present invention includes a step of forming a first gate layer, a step of stacking a second gate layer on the first gate layer, a step of etching the second gate layer into a prescribed gate pattern corresponding to a plurality of multilayer gates, a step of etching the first gate layer into the prescribed gate pattern, a step of forming sidewalls on side walls of a plurality of multilayer gates each including the first gate layer and the second gate layer etched into the gate pattern respectively, a step of embedding an interlayer dielectric film between the sidewalls of adjacent ones of the multilayer gates, and a side wall retracting step of retracting a side wall of the second gate layer beyond a side wall of the first gate layer before the formation of the sidewalls.

According to the method of manufacturing a semiconductor device, the side wall of the second gate layer is retracted beyond the side wall of the first gate layer before the formation of the sidewalls. Therefore, the second gate layer so expands in the formation of the sidewalls that a side wall surface of the second gate layer is generally flush with a side wall surface of the first gate layer, for example. In the step of embedding the interlayer dielectric film between the sidewalls, therefore, defective embedding can be prevented.

According to one embodiment of the present invention, the second gate layer is made of tungsten silicide (WSi).

According to one embodiment of the present invention, the first gate layer is made of polysilicon.

According to one embodiment of the present invention, the side wall retracting step is carried out before the etching of the first gate layer.

According to one embodiment of the present invention, the side wall retracting step is carried out after the etching of the first gate layer.

The method of manufacturing a semiconductor device according to one embodiment of the present invention further includes a step of nitriding a side wall surface of the second gate layer. Thus, a nitride film is formed on the side wall surface of the second gate layer, whereby the second gate layer can be inhibited from expanding in a subsequent step.

A third semiconductor device according to the present invention includes a first gate layer, and a second gate layer, stacked on the first gate layer, containing nitrogen on a side wall surface formed to be flush with a side wall surface of the first gate.

The semiconductor device according to one embodiment of the present invention further includes sidewalls formed on the side wall surfaces of the first gate layer and the second gate layer, and an interlayer dielectric film in contact with the sidewalls.

The foregoing and other objects, features and effects of the present invention will become more apparent from the following detailed description of the embodiments with reference to the attached drawings.

### BRIEF DESCRIPTION OF THE DRAWINGS

FIG. 1 is a schematic plan view of a semiconductor device according to an embodiment of the present invention.

FIG. 2 is a sectional view schematically showing the structure of a memory cell.

FIG. 3 is a schematic plan view partially showing a memory cell region.

FIG. 4 is a sectional view taken along a line IV-IV in FIG. 3.

FIG. 5 is a sectional view taken along a line V-V in FIG. 3.

FIG. 6 is a sectional view showing comparative example.

FIG. 7A is a schematic perspective view for illustrating a method of manufacturing the semiconductor device shown in FIGS. 3 to 5.

FIGS. 7B to 7H are schematic perspective views successively showing steps subsequent to FIG. 7A.

FIGS. 7I to 7K are schematic sectional views successively showing steps subsequent to FIG. 7H.

FIG. 8 is a sectional view taken along a line VIII-VIII in FIG. 7E.

FIGS. 9A to 9D are sectional views schematically showing the steps shown in FIGS. 7A and 7B in more detail.

FIGS. 10A to 10E are sectional views schematically showing an example of a step of forming each of gate portions shown in FIG. 7F.

FIGS. 11A to 11E are sectional views schematically showing another example of the step of forming each of the gate portions shown in FIG. 7F.

FIGS. 12A and 12B are schematic plan views showing other examples of alignment marks respectively.

FIGS. 13A and 13B are schematic sectional views showing a conventional method of manufacturing gate portions.

### DESCRIPTION OF THE PREFERRED EMBODIMENTS

An embodiment of the present invention is now described in detail with reference to the attached drawings.

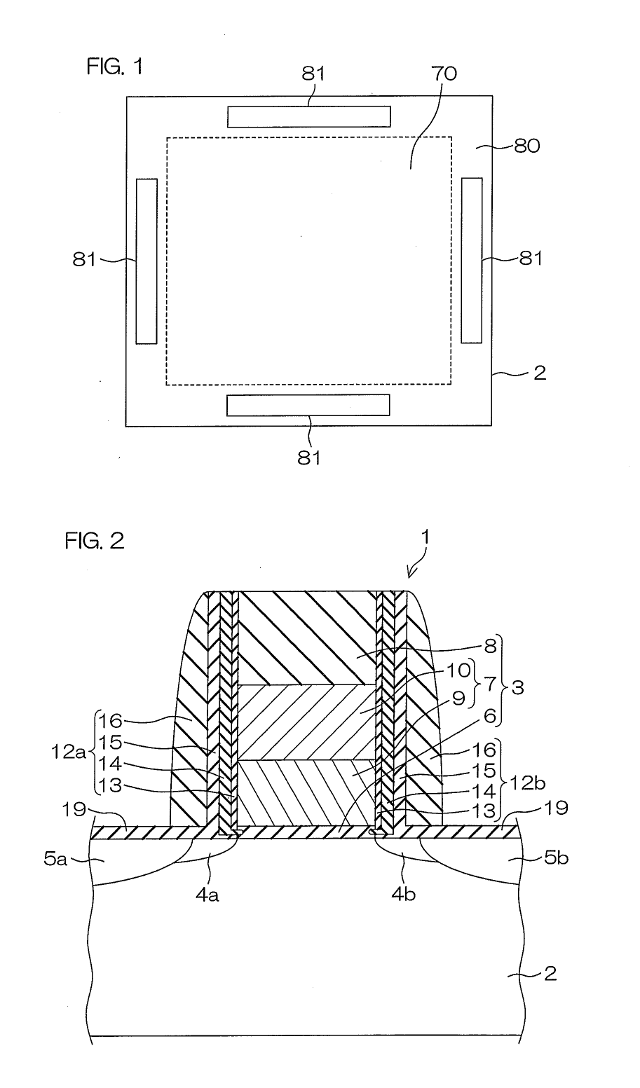

FIG. 1 is a schematic plan view of a semiconductor device according to the embodiment of the present invention.

The semiconductor device includes a silicon substrate 2 as a semiconductor substrate. A memory cell region 70 rectangular in plan view and an alignment mark region 80 in the form of a rectangular frame arranged on the periphery of the memory cell region 70 are set on one major surface of the silicon substrate 2. In the alignment mark region 80, alignment marks 81 in the form of elongated rectangles extending parallelly to the longitudinal directions of the respective sides of the memory cell region 70 in plan view are formed on portions corresponding to the respective sides of the memory cell region 70. A plurality of memory cells, not shown in FIG. 1, are provided on the memory cell region 80 in the form of an array.

FIG. 2 is a sectional view schematically showing the structure of each memory cell.

A memory cell 1 includes a MOS (Metal-Oxide-Semiconductor) field-effect transistor (hereinafter referred to as “MOS transistor”) and first and second sidewalls 12a and 12b functioning as charge storage portions. The MOS transistor includes a gate portion 3, first and second LDD (Lightly Doped Drain) regions 4a and 4b, and first and second impurity diffusion regions 5a and 5b.

The gate portion 3 includes a gate oxide film 6 formed on one major surface of the silicon substrate 2, a gate electrode 7 formed on the gate oxide film 6, and an insulating layer 8 formed on the gate electrode 7. The gate oxide film 6 is made of SiO₂, for example. The gate electrode 7 includes a polysilicon layer 9 formed on the gate oxide film 6 and a tungsten silicide layer 10 stacked on the polysilicon layer 9. In other words, the gate electrode 7 has the so-called polycide structure. The insulating layer 8 is made of SiN, for example.

The first and second LDD regions 4a and 4b are formed by diffusing an n-type impurity, for example, into regions of a surface layer portion of the silicon substrate 2 holding a channel region immediately under the gate portion 3 therebetween. The first and second impurity diffusion regions 5a and 5b are formed by diffusing an n-type impurity, for example, into regions of the surface layer portion of the silicon substrate 2 on the outer sides of the first and second LDD portions 4a and 4b respectively. Each of the first and second impurity diffusion regions 5a and 5b functions as a source region or a drain region of the MOS transistor. For example, the first and second impurity diffusion regions 5a and 5b may be used as a drain region and a source region respectively. The first and second impurity diffusion regions 5a and 5b may hereinafter be referred to as “drain region 5a” and “source region 5b” respectively.

The depth of and the impurity concentration in the first and second LDD regions 4a and 4b are rendered smaller than the depth of and the impurity concentration in the first and second impurity diffusion regions 5a and 5b. In other words, an LDD (Lightly Doped Drain) structure is employed in the MOS transistor.

The first and second sidewalls 12a and 12b are formed on one side wall and another side wall of the gate portion 3 respectively. The sidewalls closer to the drain region 5a and the source region 5b may hereinafter be referredto as “drain-side sidewall” and “source-side sidewall” respectively. The first sidewall 12a (the drain-side sidewall) is provided on the first LDD region 4a. The second sidewall 12b (the source-side sidewall) is provided on the second LDD region 4b.

Each of the sidewalls 12a and 12b has an ONON (Oxide-Nitride-Oxide-Nitride) layer structure obtained by successively stacking an inner oxide film 13, an inner nitride film 14, an outer oxide film 15 and an outer nitride film 16 on a side surface of the gate portion 3. The inner nitride film 14 is a charge storage film for storing charges. The inner oxide film 13 and the outer oxide film 15 are made of SiO₂, for example. The inner nitride film (the charge storage film) 14 and the outer nitride film 16 are made of SiN, for example.

The inner oxide film 13 is formed on a portion of a side wall surface of the gate portion 3 excluding a lower end portion. The charge storage film 14 is formed on an outer side surface of the inner oxide film 13 and the lower end portion of the side wall surface of the gate portion 3. A lower end portion of the charge storage film 14 enters a side wall of the lower end portion of the gate portion 3. The length of the portion of the charge storage film 14 entering the side wall of the lower end portion of the gate portion 3 is about 1 to 5 nm, for example. The outer oxide film 15 is formed on an outer side surface of the charge storage film 14. An oxide film 19 linked with a lower end portion of the outer oxide film 15 is formed on an exposed surface of the silicon substrate 2. The outer nitride film 16 is formed to cover an outer side surface of the outer oxide film 15 and a portion of the oxide film 19 in the vicinity of the gate portion 3.

According to the embodiment, the lower end portion of the charge storage film 14 enters the side wall of the lower end portion of the gate portion 3, whereby the charge storage film 14 easily captures hot electrons. A top oxide film covering an upper surface of the gate portion 3 and upper ends of the inner oxide film 13, the charge storage film 14 and the outer oxide film 15 may be formed on an upper side of the gate portion 3.

Operations of writing information in, reading information from and erasing information from the memory cell 1 are now described. The operation of writing information in the memory cell 1 includes a first write operation and a second write operation, for example. The operation of reading information from the memory cell 1 includes a first read operation and a second read operation, for example. The operations are now described.

### (a) First Write Operation

The source region 5b and the silicon substrate 2 are grounded, while a write voltage of 10 V, for example, is applied to the gate electrode 7, and a voltage of 6 V (higher than a source voltage), for example, is applied to the drain region 5a. Thus, electrons flow from the source region 5b toward the drain region 5a, and hot electrons formed in the vicinity of the drain region 5a jump into the charge storage film 14 in the drain-side sidewall 12a to be captured.

### (b) Second Write Operation

The drain region 5a and the silicon substrate 2 are grounded, while a write voltage of 10 V, for example, is applied to the gate electrode 7, and a voltage of 6 V (higher than a drain voltage), for example, is applied to the source region 5b. Thus, electrons flow from the drain region 5a toward the source region 5b, and hot electrons formed in the vicinity of the source region 5b jump into the charge storage film 14 in the source-side sidewall 12b to be captured.

### (c) First Read Operation

The drain region 5a and the silicon substrate 2 are grounded, while a read voltage of 3 V, for example, is applied to the gate electrode 7, and a voltage of 2 V (higher than the drain voltage), for example, is applied to the source region 5b. Thus, a high electric field is applied in the vicinity of the source region 5b. Therefore, electrons are movable even if a potential barrier is present immediately under the source-side sidewall 12b (even if the source-side sidewall 12b captures electrons). However, no high electric field is applied to the side of the drain region 5a, and hence electrons are unmovable and no current flows if a potential barrier is present immediately under the drain-side sidewall 12a (if the drain-side sidewall 12b captures electrons). If no potential barrier is present immediately under the drain-side sidewall 12a, electrons are movable, and hence a current flows. Thus, the presence or absence of electrons captured by the drain-side sidewall 12a can be detected. In other words, whether a stored value is “1” or “0” can be determined.

### (d) Second Read Operation

The source region 5b and the silicon substrate 2 are grounded, while a read voltage of 3 V, for example, is applied to the gate electrode 7, and a voltage of 2 V (higher than the source voltage), for example, is applied to the drain region 5a. Thus, a high electric field is applied in the vicinity of the drain region 5a. Therefore, electrons are movable even if a potential barrier is present immediately under the drain-side sidewall 12a (even if the drain-side sidewall 12a captures electrons). However, no high electric field is applied to the side of the source region 5b, and hence electrons are unmovable and no current flows if a potential barrier is present immediately under the source-side sidewall 12b (if the source-side sidewall 12b captures electrons). If no potential barrier is present immediately under the source-side sidewall 12b, electrons are movable, and hence a current flows. Thus, the presence or absence of electrons captured by the source-side sidewall 12b can be detected. In other words, whether a stored value is “1” or “0” can be determined.

### (e) Erase Operation

The silicon substrate 2 is grounded, while a negative voltage (an erase voltage) of −6 V, for example, is applied to the gate electrode 7, a negative voltage of −6 V is applied to the drain region 5a, and a positive voltage of 6 V is applied to the source region 5b. Thus, electron-hole pairs are created in the vicinity of the interface between the source region 5b and the drain region 5b. Holes included in the created electron-hole pairs are attracted toward the side of the gate electrode 7, to enter the sidewalls 12a and 12b. The holes entering the sidewalls 12a and 12b cancel minus charges (captured electrons) in the sidewalls 12a and 12b.

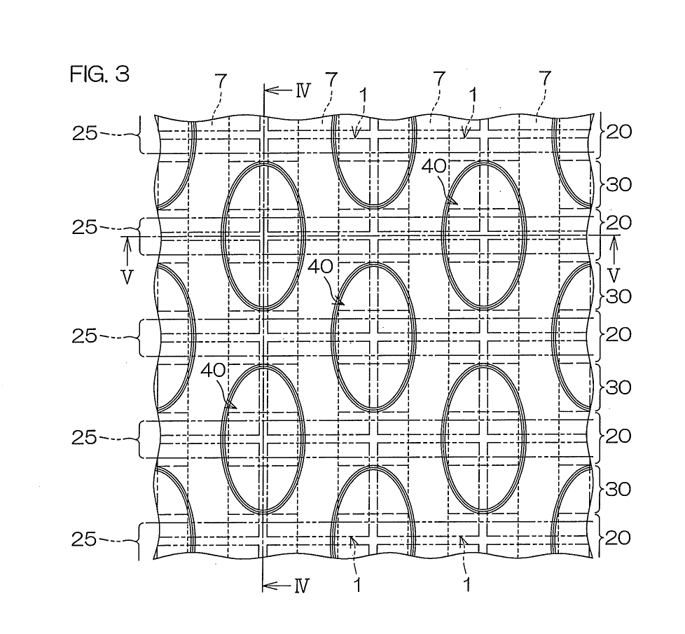

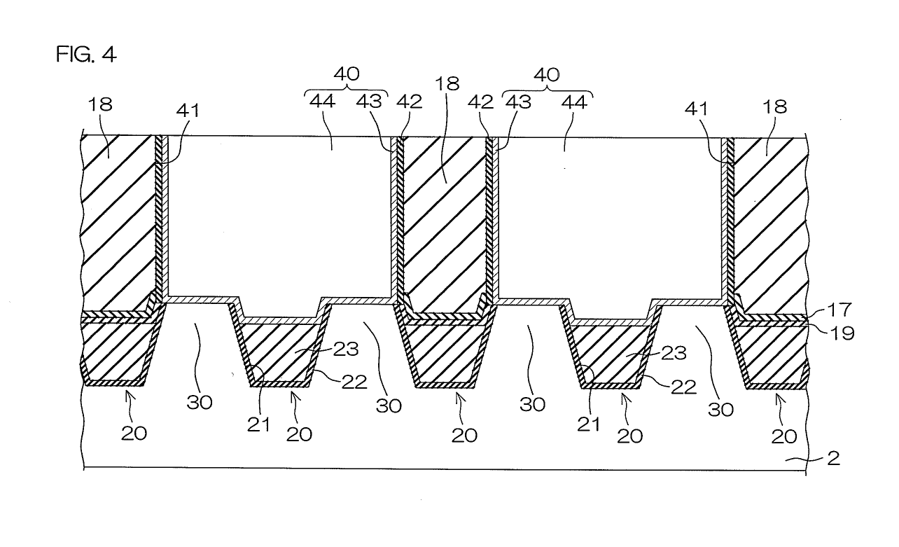

FIG. 3 is a schematic plan view partially showing the memory cell region 70 of the semiconductor device. FIG. 4 is a sectional view taken along a line IV-IV in FIG. 3. FIG. 5 is a sectional view taken along a line V-V in FIG. 3.

A plurality of linearly extending element isolation portions 20 are formed on the surface layer portion of the silicon substrate 2 parallelly to one another at prescribed intervals. A plurality of gate electrodes 7 are linearly formed in a direction orthogonal to the element isolation portions 20 in plan view parallelly to one another at prescribed intervals in the longitudinal direction of the element isolation portions 20. Regions between adjacent ones of the element isolation portions 20 form active regions 30. Linear bit lines 25 extending in the longitudinal direction of the element isolation portions 20 in plan view are arranged above the element isolation portions 20. The element isolation portions 20 include element isolation trenches 21 formed in the surface layer portion of the silicon substrate 2, liner oxide films 22 formed on inner surfaces of the element isolation trenches 21, and insulators (oxide films, for example) 23 embedded up to intermediate portions of the element isolation trenches 21 in a depth direction so that the active regions 30 between the element isolation trenches 21 protrude.

The insulators 23 are embedded not in the whole element isolation trenches 21, but up to the intermediate portions thereof in the depth direction. Therefore, the surface areas of upper portions of the active regions 30 between the adjacent element isolation portions 20 can be increased. Thus, the gate electrodes 7 are opposed to the active regions 30 with areas larger than those of regions overlapping with the active regions 30 in plan view. Therefore, gate widths can be so enlarged that high currents can be fed to channels. In other words, the MOS transistor included in each memory cell 1 has a fin transistor structure in the embodiment.

In the memory cell region 70, a plurality of memory cells 1 (gate portions 3) are formed on the silicon substrate 2 at a constant pitch (240 nm, for example) of not more than 250 nm, as shown in FIG. 5. The length (in a channel width direction) of the gate portions 3 is about 90 nm to 100 nm, for example. Each pair of memory cells 1 adjacent to each other in a direction orthogonal to the gate electrodes 7 are so formed that the positions of drain and source regions centering on the gate portions 3 (the gate electrodes 7) are opposite to one another. More specifically, the drain region of one of the memory cells 1 and the source region of the other memory cell 1 are formed by a common impurity diffusion region 5a or 5b. Therefore, drain-side sidewalls 12a or source-side sidewalls 12b face each other in each pair of memory cells 1 adjacent to each other.

A nitride film 17 made of SiN, for example, is formed on surfaces of the oxide films 19, the sidewalls 12a and 12b and the gate portions 3 provided on the silicon substrate 2. An interlayer dielectric film 18 made of BPSG (Boron Phosphorous Silicate Glass), for example, is formed on a surface of the nitride film 17. Contact plugs 40 for electrically connecting impurity diffusion regions (drain regions 5a or source regions 5b) shared by the adjacent pairs of memory cells 1 to the bit lines 25 are provided in the interlayer dielectric film 18 to pass through the same.

The contact plugs 40 include barrier metal films 43 and metal plugs 44. Side walls of the contact holes 41 formed to pass through the interlayer dielectric film 18 are covered with sealing films 42 denser than the interlayer dielectric film 18. The barrier metal films 43 are formed to cover surfaces of the sealing films 42 and bottom surface portions of the contact holes 41. The metal plugs 44 are embedded in the contact holes 41 in a state surrounded by the barrier metal films 43.

The sealing films 42 are made of SiN, for example, and the thickness thereof may be about 5 nm to 10 nm. According to the embodiment, the thickness of the sealing films 42 is about 7 nm. The barrier metal films 43 may be formed by two-layer structure films of Ti and TiN. Ti layers are in contact with the sealing films 42, and the thickness thereof may be about 30 nm. TiN layers are stacked on the Ti layers, and the thickness thereof may be about 5 nm to 100 nm, and more preferably about 10 nm to 20 nm. The metal plugs 44 are made of tungsten (W), for example. The metal plugs 44 are formed by CVD (Chemical Vapor Deposition) with source gas containing fluorine, for example. While the source gas containing fluorine is corrosive on the interlayer dielectric film 18 made of BPSG, the sealing films 42 avoid corrosion of the interlayer dielectric film 18.

According to the embodiment, the sealing films 42 denser than the interlayer dielectric film 18 are formed to cover the side walls of the contact holes 41, whereby the surfaces thereof are smooth. Therefore, the barrier metal films 43 can be brought into close contact with the sealing films 42, and can have excellent film quality with no through-holes. When the metal plugs 44 are deposited in the contact holes 41, therefore, the source gas can be prevented from reaching the interlayer dielectric film 18 through the barrier metal films 43 and the sealing films 42. Thus, the source gas containing fluorine can be prevented from corroding the interlayer dielectric film 18, or tungsten forming the metal plugs 44 can be prevented from bleeding into the interlayer dielectric film 18. In other words, a clear interface can be formed between the interlayer dielectric film 18 and the contact plugs 40, whereby abnormality such as a contact-to-contact short circuit can be suppressed.

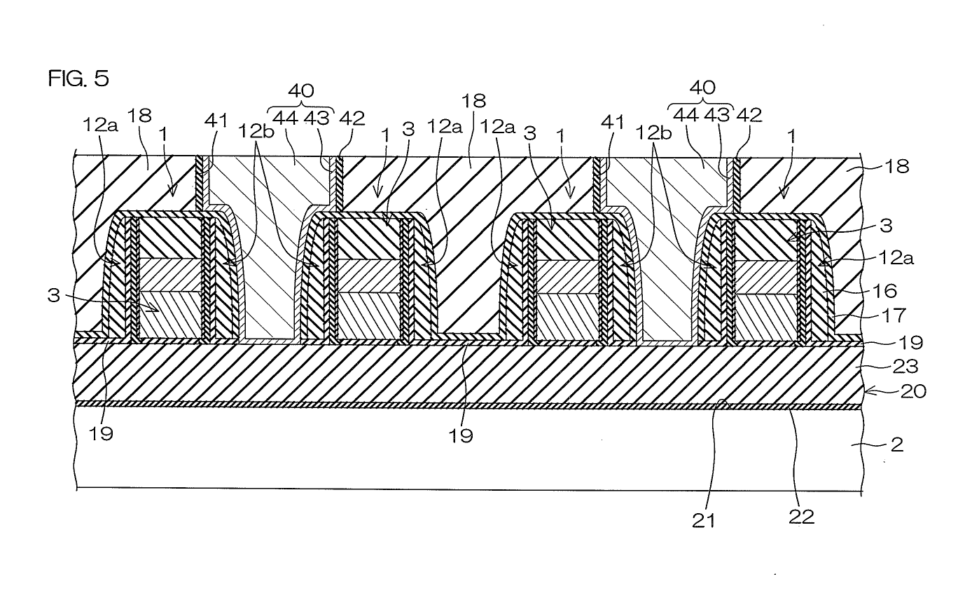

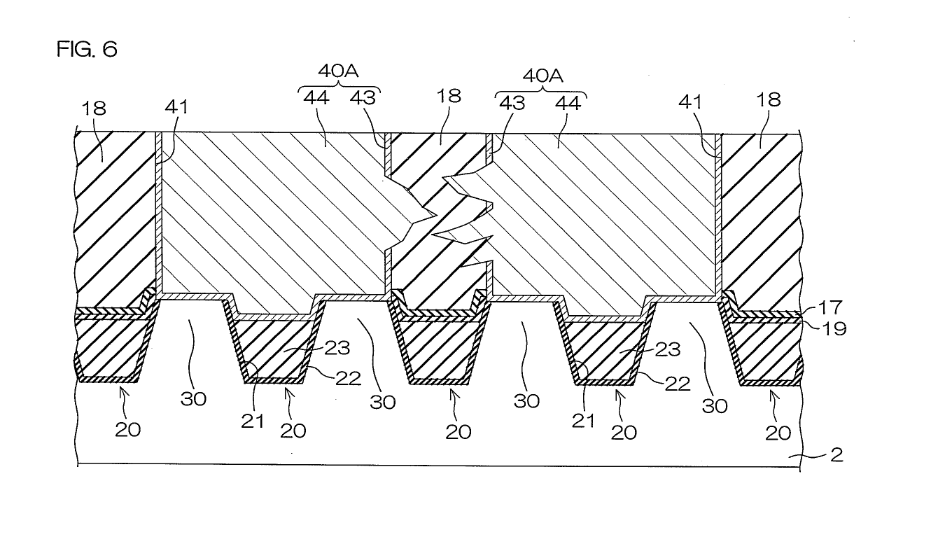

FIG. 6 is a sectional view showing comparative example. Referring to FIG. 6, portions corresponding to those in FIG. 4 are denoted by the same reference numerals. Comparative example shown in FIG. 6 includes no sealing films 42. In other words, barrier metal films 43 are in contact with side walls of contact holes 41 formed to pass through an interlayer dielectric film 18.

The interlayer dielectric film 18 made of BPSG is not dense as compared with the sealing films 42, and hence the same has a rough surface state. Therefore, adhesion between the barrier metal films 43 and the interlayer dielectric film 18 is not necessarily excellent, but through-holes may be formed in the barrier metal films 43. When metal plugs 44 are deposited in the contact holes 41, therefore, source gas containing fluorine may reach the interlayer dielectric film 18 through the barrier metal films 43. Thus, the source gas may corrode the interlayer dielectric film 18 as shown in FIG. 6, or tungsten forming the metal plugs 44 may bleed into the interlayer dielectric film 18. Such bleeding of tungsten may result in a short circuit between contact plugs 40.

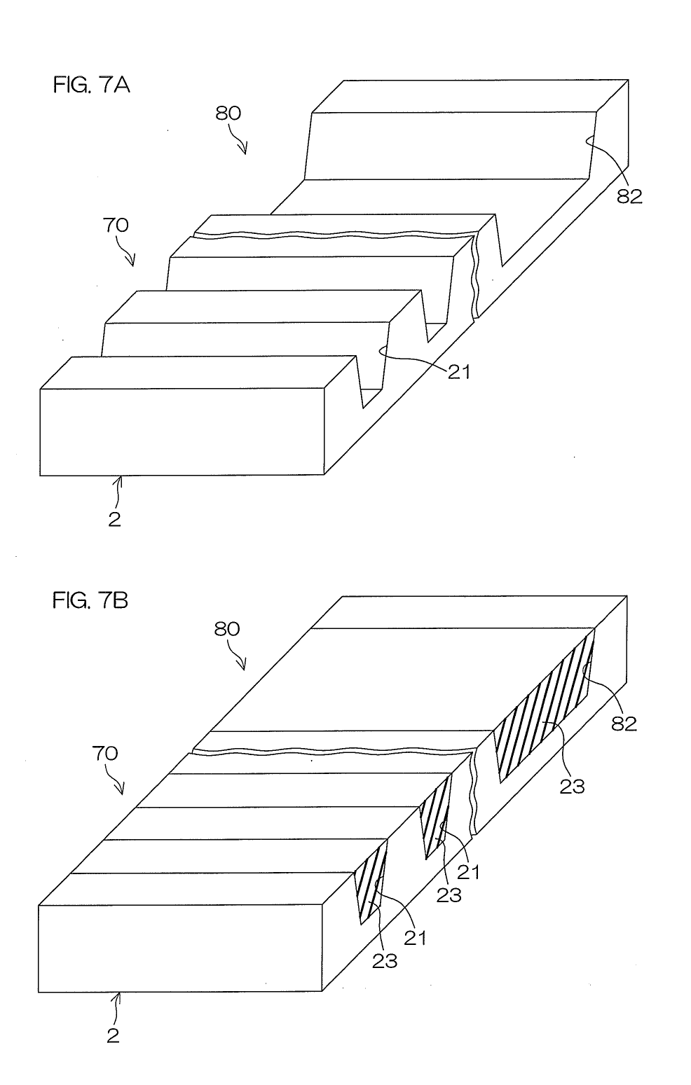

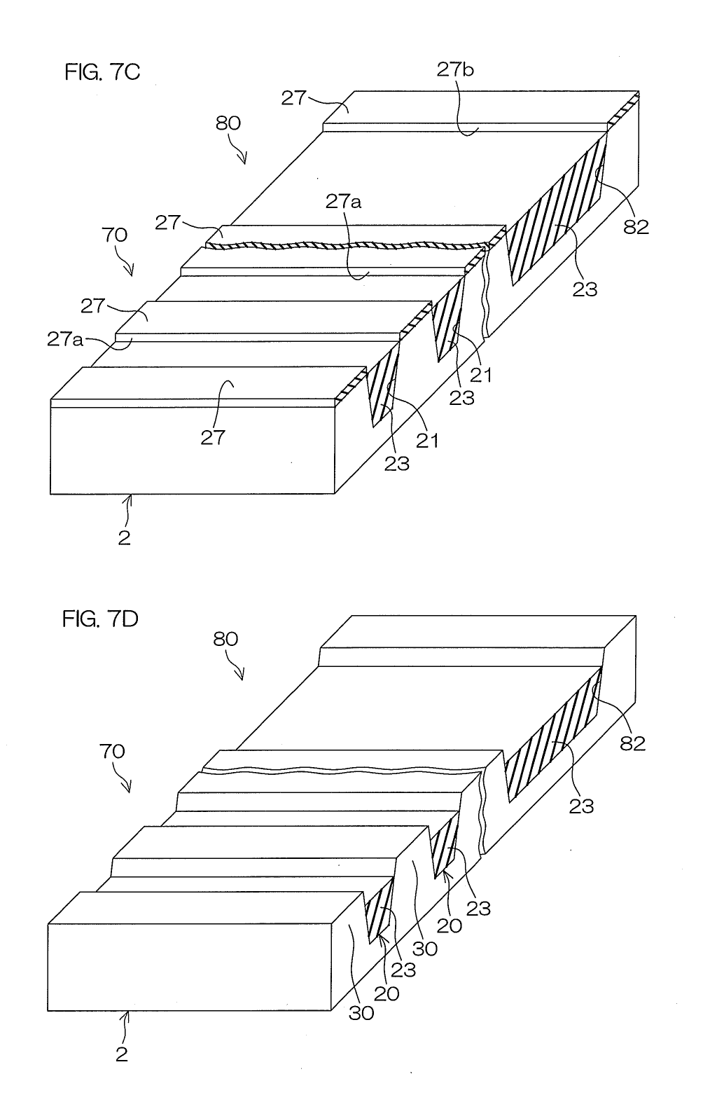

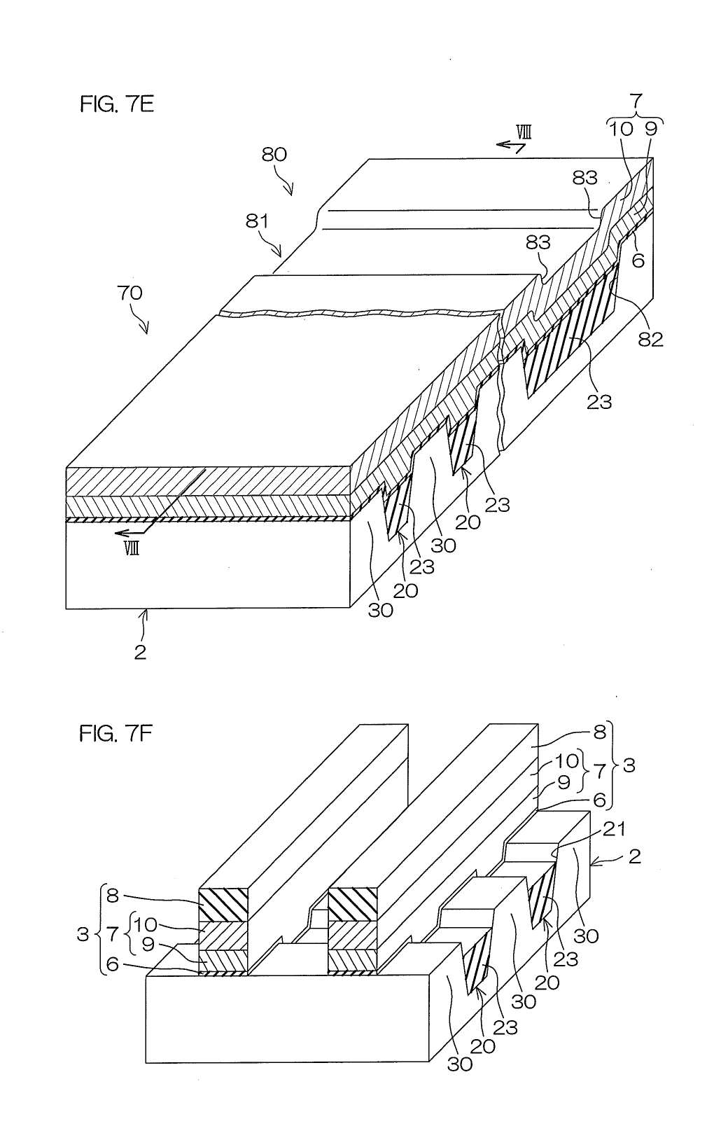

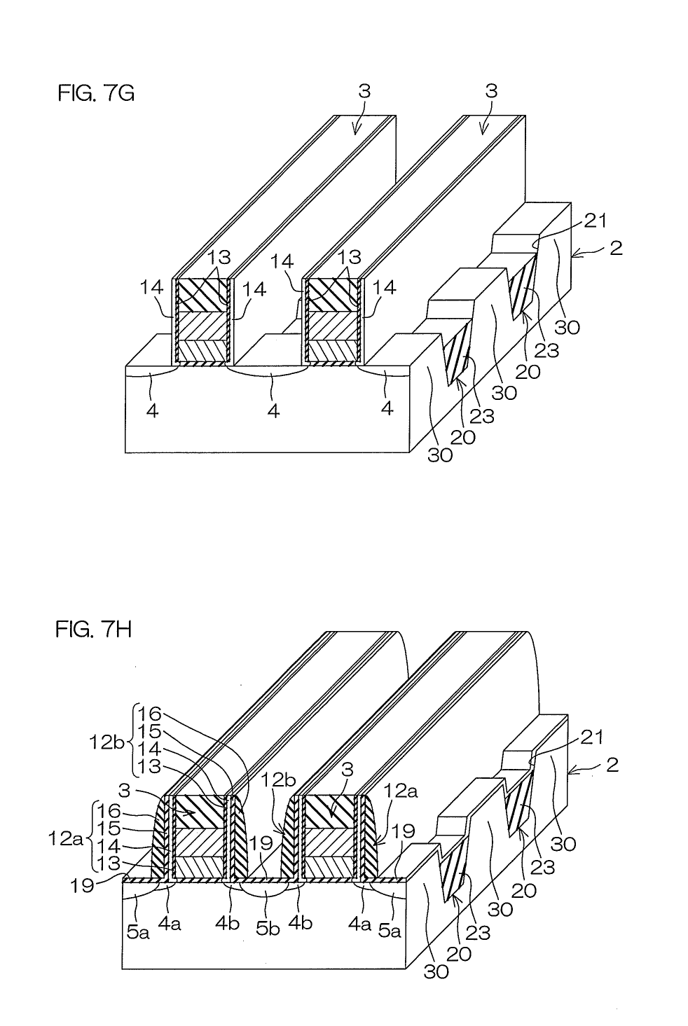

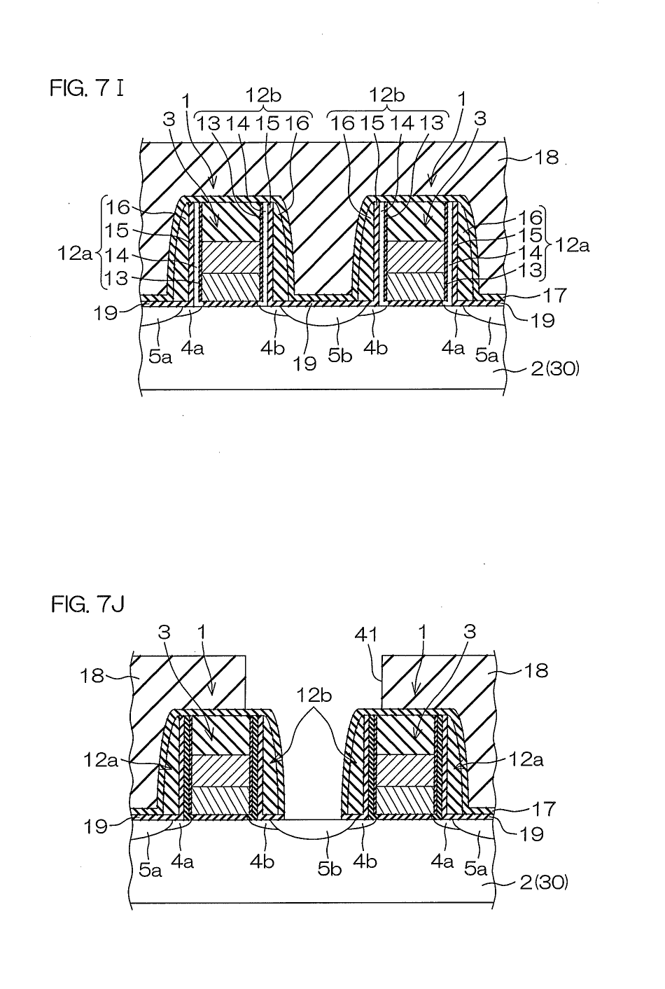

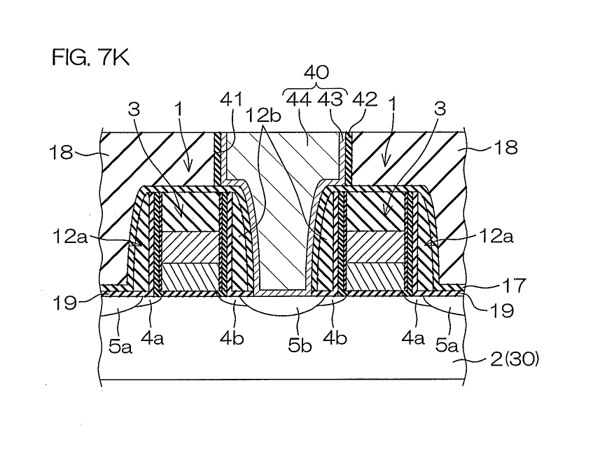

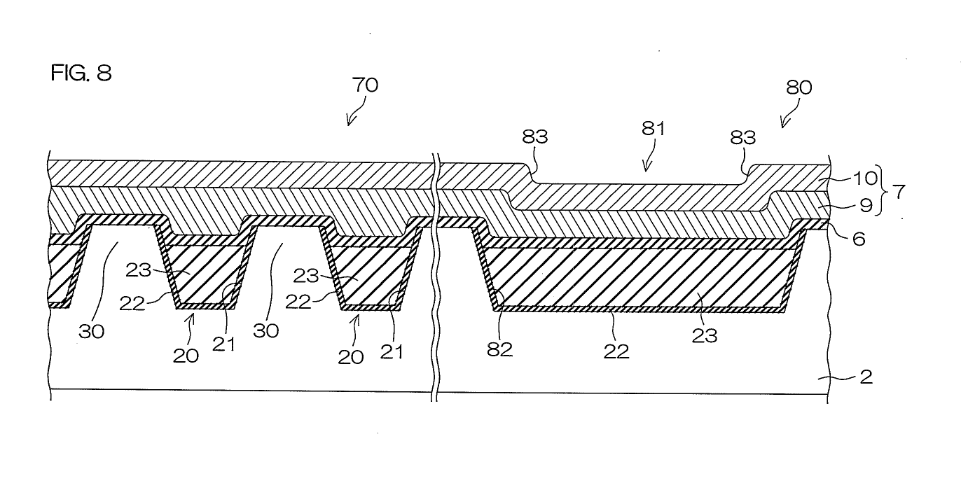

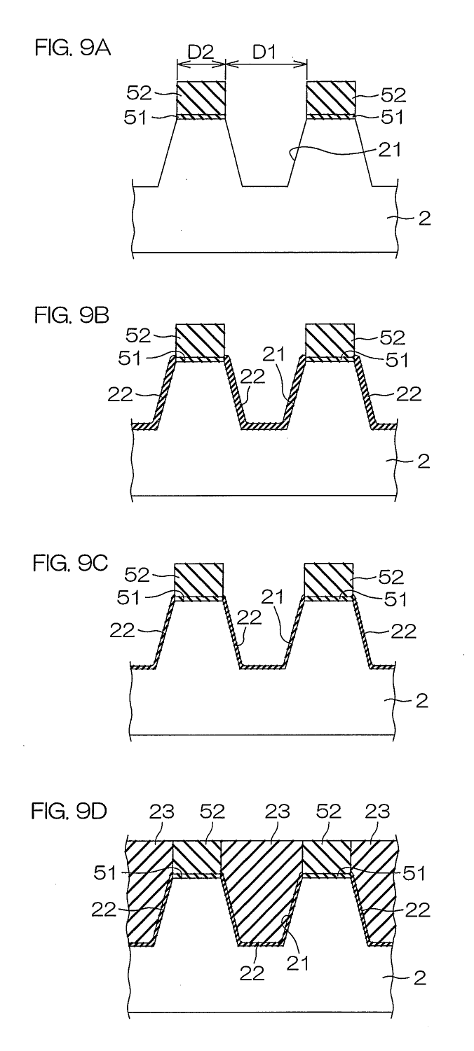

FIGS. 7A to 7H are schematic perspective views showing an example of a method of manufacturing the memory cell region 70 of the semiconductor device. FIGS. 7I to 7K are schematic sectional views successively showing steps subsequent to FIG. 7H. FIG. 8 is a sectional view taken along a line VIII-VIII in FIG. 7E. FIGS. 7A to 7E and 8 partially show the memory cell region 70 and the alignment mark region 80. FIGS. 7F to 7K partially show only the memory cell region 70.

First, an unshown pad oxide film (10 nm in thickness, for example) made of SiO₂ is formed on the silicon substrate 2 by thermal oxidation. Then, an unshown mask nitride film (80 nm in thickness, for example) is formed on the pad oxide film by CVD (Chemical Vapor Deposition). Thereafter portions of the mask nitride film and the pad oxide film corresponding to regions for forming the element isolation trenches 21 in the silicon substrate 2 and a region for forming an alignment trench 82 therein are removed by photolithography and etching. Then, the silicon substrate 2 is etched through a hard mask consisting of the mask nitride film and the pad oxide film. Thus, a plurality of linear element isolation trenches 21 are formed in the memory cell region 70 in a striped manner, as shown in FIG. 7A. Further, the linear alignment trench 82 is formed in the alignment mark region 80. The depth of the trenches 21 and 82 is about 180 nm, for example. The width of openings of the element isolation trenches 21 is about 90 nm, for example. On the other hand, the width of an opening of the alignment trench 82 is about 1 to 2 μm, for example.

Then, liner oxide films 22 (see FIGS. 4 and 8: not shown in FIGS. 7A to 7K) are formed on inner surfaces of the element isolation trenches 21 and the alignment trench 82 by thermal oxidation. Then, the silicon substrate 2 is heat-treated in a nitrogen atmosphere. Thereafter the thicknesses of the liner oxide films 22 are reduced. Then, insulators (oxide films) 23 made of SiO₂ are deposited on the silicon substrate 2 including inner portions of the element isolation trenches 21 and the alignment trench 82 by HDP (High Density Plasma)-CVD, for example. Thereafter the insulators 23 are polished from surfaces thereof by CMP (Chemical Mechanical Polishing). The insulators 23 are continuously polished until the surfaces thereof are flush with a surface of the mask nitride film. Thus, the insulators 23 are embedded in the element isolation trenches 21 and the alignment trench 82, as shown in FIG. 7B.

FIGS. 9A to 9D are sectional views schematically showing the steps from the formation of the element isolation trenches 21 and the alignment trench 82 shown in FIG. 7A up to the deposition of the insulators 23 in the element isolation trenches 21 and the alignment trench 82 shown in FIG. 7B in more detail. While FIGS. 9A to 9D show only the steps from the formation of the element isolation trenches 21 up to the deposition of the insulators 23 in the element isolation trenches 21, the steps from the formation of the alignment trench 82 up to the deposition of the insulator 23 in the alignment trench 82 are similar thereto.

FIG. 9A shows a state where each element isolation trench 21 is formed in the surface layer portion of the silicon substrate 2. The element isolation trench 21 is formed by etching the silicon substrate 2 through a hard mask consisting of a pad oxide film 51 and a mask nitride film 52, as described above. According to the embodiment, the width D1 of the upper surface of the element isolation trench 21 is about 80 to 100 nm (90 nm, for example). The width D2 of the upper surfaces of the active regions 30 is about 80 to 100 nm.

Then, the inner surface of the element isolation trench 21 is liner-oxidized (thermally oxidized), as shown in FIG. 9B. The liner oxidation is performed at a temperature of 1000° C., in order to prevent the inner surface of the element isolation trench 21 from nitriding resulting from subsequent heat treatment. As a result of the liner oxidation, the liner oxide film 22 having a generally uniform thickness is grown on the inner surface of the element isolation trench 21. An initial thickness of the liner oxide film 22 is set to not less than 8 nm (80 Å). According to the embodiment, the initial thickness of the liner oxide film 22 is about 10 nm (100 Å).

Thereafter the silicon substrate 2 is heat-treated in a nitrogen atmosphere. The temperature of the nitrogen atmosphere is 1100° C. to 1200° C. (1150° C., for example) higher than that in the formation of the liner oxide film 22, and the time of the heat treatment is about six hours. The heat treatment is performed in order to cure crystal defects caused on edge portions of the active regions 30 due to stress of the mask nitride film 52. More specifically, high stress is applied to edge portions of the mask nitride film 52, to cause crystal defects in the edge portions of the active regions 30. The crystal defects are repaired by the heat treatment in the nitrogen atmosphere. The heat treatment is performed in the state where the thick liner oxide film 22 is formed on the inner surface of the element isolation trench 21, whereby silicon surfaces on the side walls of the element isolation trench 21 can be prevented from nitriding. Therefore, crystallinity is not deteriorated (no dislocations are formed) due to an unintended nitride film applying high stress.

Then, the thickness of the liner oxide film 22 is reduced to not more than half the initial thickness by etching, as shown in FIG. 9C. According to the embodiment, the thickness of the liner oxide film 23 is reduced to about 5 nm. Thus, the final thickness of the liner oxide film 23 can be reduced, whereby the width D1 of the element isolation trench 21 can be previously narrowed in response thereto. Thereafter the insulator (the oxide film) 23 made of SiO₂ is formed on the liner oxide film 23 formed on the inner surface of the element isolation trench 21 and the mask nitride film 52 formed on the silicon substrate 2 by HDP-CVD. Then, the insulator 23 is polished from the surface thereof by CMP. The insulator 23 is continuously polished until the surface thereof is flush with the surface of the mask nitride film 52. Thus, the insulator 23 is embedded in the element isolation trench 21, as shown in FIG. 9D.

In the resultant obtained in this manner, no nitride films are present on the silicon surfaces on the side walls of the element isolation trench 21, despite the small thickness of the liner oxide film 22. Further, both side edges of a bottom portion of the element isolation trench 21 are chamfered, despite the small thickness of the liner oxide film 22. If a thin liner oxide film is formed in an initial stage and the thickness thereof is not reduced, the shapes of both side edges of the bottom portion of the element isolation trench 21 follow the initial shape of the element isolation trench 21. If a thick liner oxide film is formed in the initial stage, on the other hand, the shapes of both side edges of the bottom portion of the element isolation trench 21 are rounded. When a thick liner oxide film is formed in the initial stage and the thickness thereof is reduced after the heat treatment as in the embodiment, therefore, the shapes of both side edges of the bottom portion of the element isolation trench 21 are rounded, despite the small thickness of the liner oxide film.

Referring again to FIG. 7B, the mask nitride film 52 is removed from the silicon substrate 2 by photolithography and etching. Then, the pad oxide film 51 is removed from the silicon substrate 2 by etching. Then, the insulators (the oxide films) 23 in the element isolation trenches 21 and the alignment trench 82 are dug down by photolithography and etching, as shown in FIGS. 7C and 7D. The insulators 23 in the element isolation trenches 21 and the alignment trench 82 are simultaneously dug down through one mask.

In other words, a photoresist film 27 is formed to cover the surfaces of the insulators 23 and the silicon substrate 2, as shown in FIG. 7C. A photomask is arranged on the photoresist film 27, to expose the photoresist film 27 there through. Then, the photoresist film 27 is developed, whereby unexposed portions, for example, are removed from the photoresist film 27. Thus, openings 27a and 27b are formed in the photoresist film 27 to expose the insulators 23 from the element isolation trenches and the alignment trench 82 respectively. Then, the insulators 23 in the element isolation trenches 21 and the alignment trench 82 are simultaneously dug down by etching through the photoresist film 27 employed as a mask, as shown in FIG. 7D. Thereafter the photoresist film 27 is removed (by ashing).

Therefore, the depth (the quantity of digging) from the surface of the silicon substrate 2 up to the surfaces of the insulators 23 in the element isolation trenches 21 and the depth of digging (the quantity of digging) from the surface of the silicon substrate 2 up to the surface of the insulator 23 in the alignment trench 82 are generally equal to each other. The quantities of digging may be about 26 nm, for example. Thus, element isolation portions 20 are formed in the memory cell region 70. Regions of the surface layer portion of the silicon substrate 2 between adjacent ones of the element isolation portions 20 form active regions 30. In other words, the element isolation portions 20 are so formed that a plurality of linear active regions 30 are formed in a striped manner. The insulators 23 in the element isolation trenches 21 correspond to the “first insulating film” in Claims, and the insulator 23 in the alignment trench 82 corresponds to the “second insulating film” in Claims.

Referring to FIGS. 7E and 8, a gate oxide film 6 (7 nm in thickness, for example) made of SiO₂ is formed on the surface of the silicon substrate 2 and the surfaces of the insulators 23 in the trenches 21 and 82 by thermal oxidation, for example. Then, a polysilicon layer 9 (70 nm in thickness, for example) is formed on the gate oxide film 6 by CVD. Thereafter an impurity (P (phosphorus), for example) is introduced into the polysilicon layer 9 by ion implantation. Then, a tungsten silicide layer 10 (100 nm in thickness, for example) is stacked on the polysilicon layer 9 by CVD. The polysilicon layer 9 and the tungsten silicide layer 10 constitute a metal film (hereinafter referred to as “gate metal film”), in order to form a gate electrode 7.

In the memory cell region 70, a surface of the gate metal film (a surface of the tungsten silicide layer 10) is planar, due to the small width of the element isolation trenches 21. In the alignment mark region 80, on the other hand, observable step portions 83 are formed on the surface of the gate metal film (the surface of the tungsten silicide layer 10) on the alignment trench 82, due to the large width of the alignment trench 82. A portion of the gate metal film having the step portions 83 forms an alignment mark 81.

Then, an insulating layer 8 (180 nm in thickness, for example) made of SiN is formed on the tungsten silicide layer 10 by CVD in the memory cell region 70. In the memory cell region 70, further, a multilayer body including the gate oxide film 6, the polysilicon layer 9, the tungsten silicide layer 10 and the insulating layer 8 is patterned by photolithography and etching. Thus, a plurality of linear gate portions 3 are formed in a striped manner, as shown in FIG. 7F. Each gate portion 3 includes the gate oxide film 6, the gate electrode 7 consisting of the polysilicon layer 9 and the tungsten silicide layer 10, and the insulating layer 8.

The patterning step is more specifically described. First, a photoresist is applied onto the insulating layer 8. Then, a photomask is formed on the photoresist, to expose the photoresist therethrough. The photomask is aligned with the silicon substrate 2 by observing the step portions 83 of the alignment mark 81. Then, the photoresist is developed, whereby unexposed portions, for example, are removed from the photoresist. Thereafter the multilayer body of the gate oxide film 6, the polysilicon layer 9, the tungsten silicide layer 10 and the insulating layer 8 is etched, and the gate portions 3 are formed. Finally, the photoresist is removed (by ashing).

Then, an impurity for forming an LDD structure is introduced into regions of surface layer portions of active regions 30 holding channel regions immediately under the gate portions 3 therebetween by ion implantation, as shown in FIG. 7G. Thus, LDD portions 4 are formed. Thereafter inner oxide films 13 made of SiO₂ are formed by CVD, for example, to cover side wall surfaces of the gate portions 3 and the surface of the silicon substrate 2. Thereafter the oxide films 13 are removed from the silicon substrate 2 while leaving portions on the side wall surfaces of the gate portions 3 by photolithography and etching. The portions of the oxide films 13 left on the side wall surfaces of the gate portions 3 form the inner oxide films 13.

When the oxide films 13 are removed from the silicon substrate 2 by etching, the oxide films 13 on surfaces of lower end portions of side walls of the gate portions 3 and surface portions of lower end portions of the side walls of the gate portions 3 are removed. Thus, recess portions extending in the direction of the gate electrode 7 are formed on the lower end portions of the side wall surfaces of the gate portions 3. Then, charge storage films 14 made of SiN are formed on the inner oxide films 13 and the lower end portions of the side wall surfaces of the gate portions 3 by LP-CVD (Low pressure Chemical Vapor Deposition), for example. Lower end portions of the charge storage films 14 enter the recess portions on the lower end portions of the side wall surfaces of the gate portions 3.

Then, outer oxide films 15 are formed on side wall surfaces of the charge storage films 14 while an oxide film 19 is simultaneously formed on the surface of the silicon substrate 2 by CVD, for example, as shown in FIG. 7H. Then, a nitride film made of SiN is formed on the overall surface of the memory cell region 70 by CVD, for example. Portions (more specifically, central portions of regions of the oxide film 19 exposed from the spaces between the adjacent ones of the gate portions 3 in the width direction) of the nitride film are removed by etching, whereby outer nitride films 16 are formed to cover surfaces of the outer oxide films 15 and surfaces of portions of the oxide film 19 in the vicinity of the gate portions 3. Thus, drain-side sidewalls 12a and source-side sidewalls 12b each having an ONON structure are formed on both side walls of the gate portions 3.

Thereafter an impurity for creating drain regions and source regions is ion-implanted into regions of the surface layer portions of the active regions 30 corresponding to portions where the oxide film 19 is exposed from the outer nitride films 16. Thus, drain regions 5a and a source region 5b are formed, and the LDD portions 4 are divided into LDD portions 4a and 4b. Then, heat treatment is performed for activating the impurity ions introduced into the drain regions 5a and the source region 5b as well as into the LDD portions 4a and 4b. Thus, a plurality of memory cells 1 are formed in the memory cell region 70.

Then, a nitride film 17 functioning as an etching stopper film is formed on the overall surface of the memory cell region 70 by low pressure CVD, for example, as shown in FIG. 7I. Thereafter an interlayer dielectric film 18 made of BPSG is formed on the nitride film 17 by CVD. Then, the interlayer dielectric film 18 is planarized by CMP.

Then, a contact hole 41 passing through the interlayer dielectric film 18 is formed in a region of the interlayer dielectric film 18 corresponding to the space between each adjacent pair of gate portions 3 by plasma etching, for example, as shown in FIG. 7J. When the contact hole 41 is formed, out of the oxide film 19 and the nitride film 17 disposed on the silicon substrate 2 and the insulators 23 in the element isolation trenches 21, those portions corresponding to regions where the contact hole 41 is formed in plan view are removed. Then, a sealing film 42 (7 nm in thickness, for example) made of SiN is formed to cover a side wall of the contact hole 41 by low pressure CVD, for example, as shown in FIG. 7K. Then, a barrier metal film 43 having a two-layer structure of Ti and TiN (with a Ti layer of 30 nm in thickness and a TiN layer of 5 nm to 100 nm, more preferably 10 nm to 20 nm in thickness, for example) is formed to cover a surface of the sealing film 42 in the contact hole 41 and a bottom surface portion of the contact hole 41. The Ti layer is formed by sputtering, for example, and the TiN layer is formed by CVD, for example. Then, tungsten (W) is grown on the overall surface including an inner portion of the contact hole 41 surrounded by the barrier metal film 43 by CVD with WF₆ gas. Thereafter tungsten and portions of the barrier metal film 43 and the sealing film 42 outside the contact hole 41 are removed by CMP.

Thus, such a structure is obtained that a metal plug 44 made of tungsten is embedded in the contact hole 41 in the state surrounded by the barrier metal film 43. A contact plug 40 passing through the interlayer dielectric film 18 is formed in the interlayer dielectric film 18 in this manner. FIG. 7K shows an example of the contact plug 40 electrically connected to the source region (common to the adjacent pair of memory cells 1) 5b between two gate portions 3.

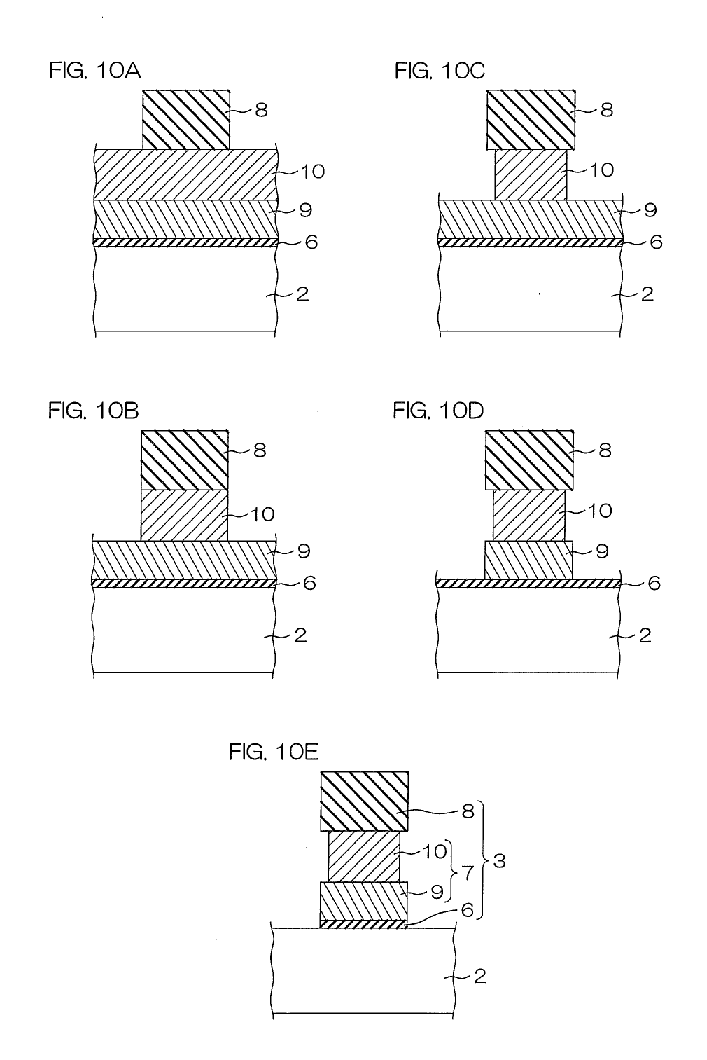

FIGS. 10A to 10F are sectional views showing an example of a step of forming each of the gate portions 3 shown in FIG. 7F.

First, the gate oxide film 6, the polysilicon layer (a first gate layer) 9, the tungsten silicide layer (a second gate layer) 10 and the insulating layer 8 are formed on the surface of the silicon substrate 2. Thereafter the insulating layer 8 is etched into a prescribed gate pattern by photolithography and etching, as shown in FIG. 10A. The gate pattern is a pattern corresponding to a plurality of gate portions 3. In practice, therefore, a plurality of insulating layers 8 shown in FIG. 10A are formed correspondingly to the plurality of gate portions 3.

Then, the tungsten silicide layer 10 is etched into the prescribed gate pattern by plasma etching with mixed gas of chlorine gas (Cl₂) and oxygen gas (O₂), for example, through the insulating layer 8 employed as a hard mask, as shown in FIG. 10B. In this case, the flow rate of the chlorine gas (Cl₂) is set to 240 sccm, and that of the oxygen gas (O₂) is set to 14 sccm, for example.

Then, the flow ratios of the chlorine gas (Cl₂) and the oxygen gas (O₂) are changed in the etching gas. For example, the flow rate of the chlorine gas (Cl₂) is set to 160 sccm, and that of the oxygen gas (O₂) is set to 50 sccm. In other words, the flow ratio of the oxygen gas (O₂) is set higher. Thus, the etching rate for tungsten silicide is increased, whereby side walls of the tungsten silicide layer 10 are retracted, as shown in FIG. 10C.

Then, plasma etching is performed anew while switching the etching gas to mixed gas of hydrogen bromide gas (HBr) and oxygen gas (O₂), for example, whereby the polysilicon layer 9 is etched into the prescribed gate pattern, as shown in FIG. 10D. In this case, the flow rate of the hydrogen bromide gas (HBr) is set to 264 sccm, and that of the oxygen gas (O₂) is set to 4 sccm, for example. Thereafter surfaces (side surfaces) of the tungsten silicide layer 10 are nitrided by heat treatment in a nitrogen atmosphere, in order to suppress expansion of the tungsten silicide layer 10 by forming nitride films on the surfaces of the tungsten silicide layer 10. Therefore, the tungsten silicide layer 10 contains nitrogen in side wall surfaces thereof.

Thereafter the gate oxide film 6 is etched into the prescribed gate pattern, as shown in FIG. 10E. Thus, the gate portion 3 is formed.

When the gate portions 3 are formed, the LDD portions 4 are formed on the surface layer portions of the active regions 30, as described with reference to FIG. 7G. Thereafter the sidewalls 12a and 12b are formed on both side surfaces of the gate portions 3, as described with reference to FIGS. 7G and 7H. More specifically, the inner oxide films 13 made of SiO₂ are formed to cover upper portions of both side edges of the LDD portions 4 on the surface of the silicon substrate 2 and the side wall surfaces of the gate portions 3. Then, the inner nitride films (the charge storage films) 14 made of SiN are formed on the surfaces of the inner oxide films 13 by LP-CVD. Further, the outer oxide films 15 are formed on the surfaces of the inner nitride films 14. In addition, the outer nitride films 16 are formed on the surfaces of the outer oxide films 15. Thus, the sidewalls 12a and 12b having four-layer structures of ONON are formed on both side wall surfaces of the gate portions 3 respectively.

The tungsten silicide layers 10 of the gate portions 3 expand in the thermal oxidation for forming the inner oxide films 13 and the formation of the outer oxide films 15 by LP-CVD. According to the embodiment, however, the side surfaces of the tungsten silicide layers 10 are previously retracted as described above, whereby the tungsten silicide layers 10 so expand that the side wall surfaces thereof are generally flush with those of the polysilicon layers 9. In other words, the side wall surfaces of the tungsten silicide layers 10 do not project outward beyond those of the polysilicon layers 9. Thus, the intervals between the sidewalls of the adjacent memory cells 1 can be prevented from being locally narrowed, and the interlayer dielectric film 18 can be prevented from defective embedding. Further, the impurity can be easily introduced also into portions of the surface layer portion of the silicon substrate 2 in the vicinity of the sidewalls in the ion implantation of the impurity for forming the drain regions 5a and the source region 5b. Thus, the semiconductor device is protected against reduction of a driving current or reduction of an operating speed, whereby device characteristics can be easily obtained as designed.

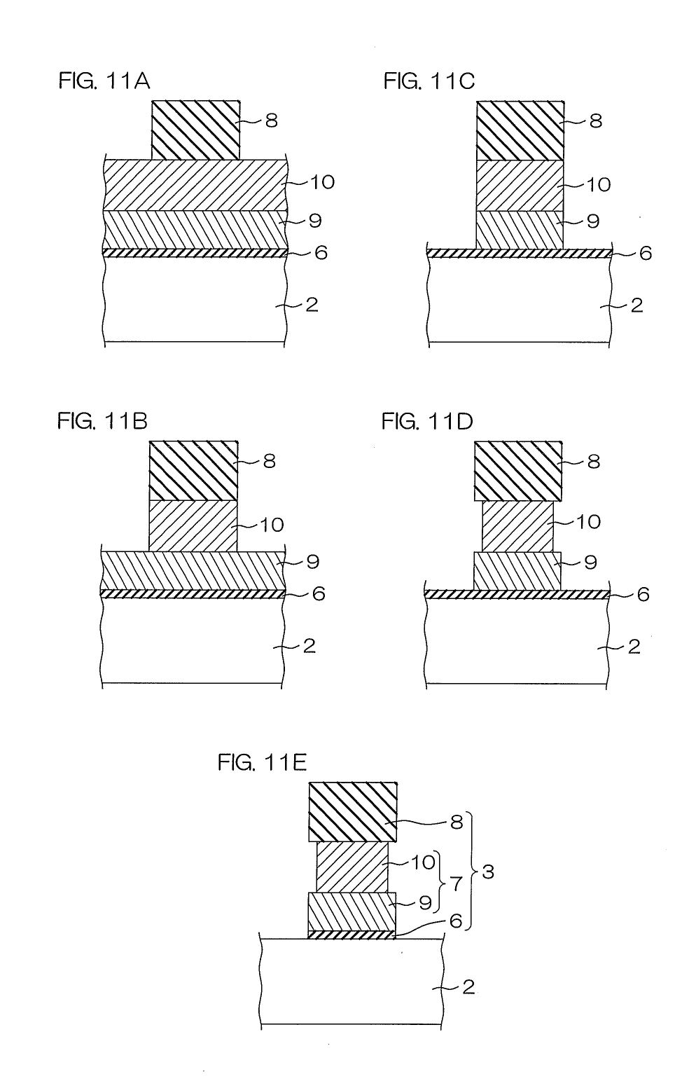

FIGS. 11A to 11F are sectional views showing another example of the step of forming each of the gate portions 3 shown in FIG. 7F.

First, the gate oxide film 6, the polysilicon layer (the first gate layer) 9, the tungsten silicide layer (the second gate layer) 10 and the insulating layer 8 are formed on the surface of the silicon substrate 2. Thereafter the insulating layer 8 is etched into a prescribed gate pattern by photolithography and etching, as shown in FIG. 11A. The gate pattern is a pattern corresponding to a plurality of gate portions 3. In practice, therefore, a plurality of insulating layers 8 shown in FIG. 11A are formed correspondingly to the plurality of gate portions 3.

Then, the tungsten silicide layer 10 is etched into the prescribed gate pattern by plasma etching with mixed gas of chlorine gas (Cl₂) and oxygen gas (O₂), for example, through the insulating layer 8 employed as a hard mask, as shown in FIG. 11B.

Thereafter plasma etching is performed anew while switching the etching gas to mixed gas of hydrogen bromide gas (HBr) and oxygen gas (O₂), for example, whereby the polysilicon layer 9 is etched into the prescribed gate pattern, as shown in FIG. 11C.

Then, the side walls of the tungsten silicide layer 10 are retracted by wet etching with an ammonia and hydrogen peroxide mixture (APM), for example, employed as an etching solution, as shown in FIG. 11D. Thereafter the surfaces (the side surfaces) of the tungsten silicide layer 10 are nitrided by heat treatment in a nitrogen atmosphere, in order to suppress expansion of the tungsten silicide layer 10 by forming nitride films on the surfaces of the tungsten silicide layer 10. Therefore, the tungsten silicide layer 10 contains nitrogen in the side wall surfaces thereof.

Then, the gate oxide film 6 is etched into the prescribed gate pattern, as shown in FIG. 11E. Thus, the gate portion 3 as a multilayer gate is formed.

While the embodiment of the present invention has been described, the present invention may be embodied in other ways. For example, the interlayer dielectric film 18, made of BPSG in the aforementioned embodiment, may alternatively be formed by another insulating film made of SiO₂ or the like. The sealing films 42, made of SiN, may alternatively be formed by multilayer films of SiO₂ and SiN, for example. In this case, the multilayer films of SiO₂ and SiN may be formed on the inner surfaces of the contact holes 41, with nitride films (SiN) arranged closer to the barrier metal films 43. The present invention is also applicable to contact plugs for elements other than memory cells.

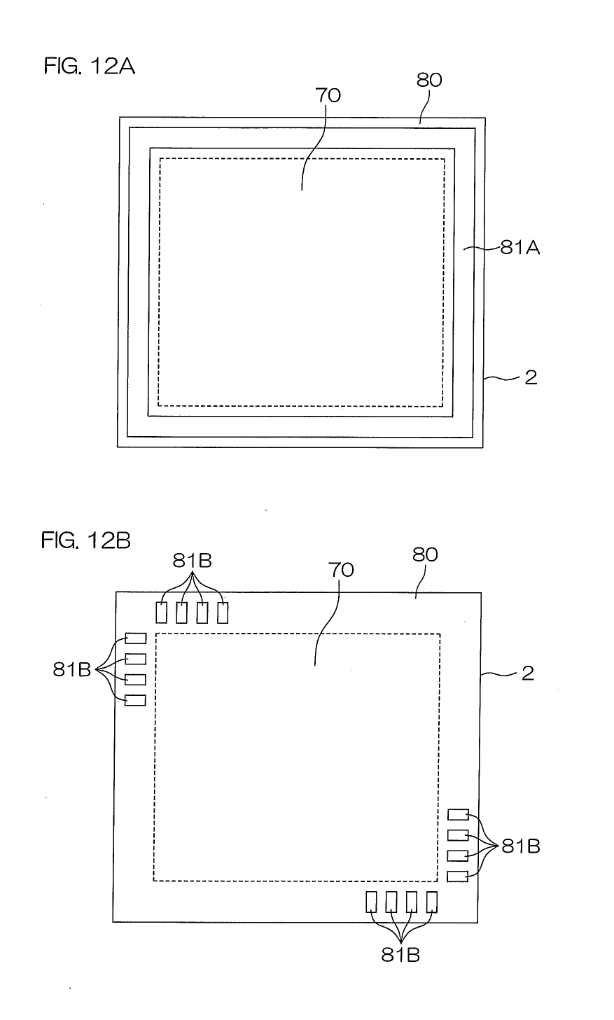

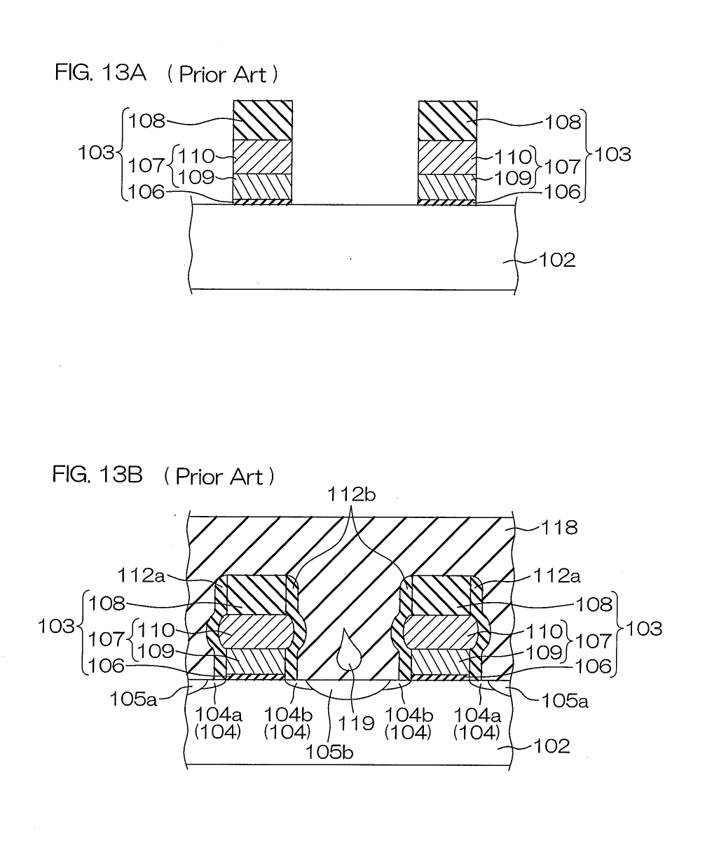

An alignment mark or alignment marks may have a shape or shapes and arrangement shown in FIG. 12A or 12B. In the example shown in FIG. 12A, an alignment mark 81A in the form of a rectangular frame in plan view is formed on an alignment mark region 80, to surround a memory cell region 70. In the example shown in FIG. 12B, on the other hand, a plurality of oblong alignment marks 81B are formed along two pairs of sides of a memory cell region 70 inside an alignment mark region 80 respectively in the vicinity of two opposed corner portions of the alignment mark region 80.

While the hard mask consisting of the insulating layer 8 is employed as the mask for etching the tungsten silicide layer 10 and the polysilicon layer 9 in the method of manufacturing each of the gate portions 3 described with reference to FIGS. 10A to 10E or FIGS. 11A to 11E, a TEOS/SiN mask, a TEOS mask, a resist mask or the like may alternatively be employed. While the side walls of the tungsten silicide layer 10 are retracted by wet etching in the method of manufacturing each of the gate portions 3 described with reference to FIGS. 11A to 11E, the same may alternatively be retracted by dry etching. Further, the second gate layer, formed by the tungsten silicide layer 10 in the aforementioned embodiment, may alternatively be made of tungsten.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

What is claimed is:

1. A semiconductor device comprising:
an interlayer dielectric film;
a sealing film, formed to cover a side wall of a contact hole formed to pass through the interlayer dielectric film, denser than the interlayer dielectric film;
a barrier metal film formed to cover a surface of the sealing film and a bottom surface portion of the contact hole; and
a metal plug embedded in the contact hole in a state surrounded by the barrier metal film.

2. The semiconductor device according to claim 1, wherein
the sealing film is formed by a nitride film.

3. The semiconductor device according to claim 1, wherein
the interlayer dielectric film is made of BPSG.

4. The semiconductor device according to claim 1, wherein
the metal plug is made of tungsten.

5. The semiconductor device according to claim 1, further comprising a plurality of gate portions formed at a pitch of not more than 250 nm, wherein
the contact hole is formed between adjacent ones of the gate portions.

6. The semiconductor device according to claim 5, wherein
each of the gate portions has a multilayer structure of a plurality of layers.

7. A method of manufacturing a semiconductor device, comprising the steps of:
forming an interlayer dielectric film on a semiconductor substrate;
forming a contact hole passing through the interlayer dielectric film;
forming a sealing film denser than the interlayer dielectric film to cover a side wall of the contact hole;
forming a barrier metal film covering a surface of the sealing film and a bottom surface portion of the contact hole; and
forming a metal plug embedded in the contact hole in a state surrounded by the barrier metal film with source gas having corrosiveness on the interlayer dielectric film.

8. The method of manufacturing a semiconductor device according to claim 7, wherein
the sealing film is formed by a nitride film.

9. The method of manufacturing a semiconductor device according to claim 7, wherein
the interlayer dielectric film is formed by an oxide film, and
the step of forming the metal plug includes a step of forming the metal plug with source gas containing fluorine.

10. A semiconductor memory comprising:
a semiconductor substrate having a memory cell region provided with an element isolation trench isolating an active region and an alignment mark region provided with an alignment trench for mask alignment;
a first insulating film, embedded up to an intermediate portion of the element isolation trench in a depth direction so that the active region between the element isolation trench and another element isolation trench protrudes, having a surface on a position deeper than the semiconductor substrate; and
a second insulating film embedded up to an intermediate portion of the alignment trench in a depth direction.

11. The semiconductor memory according to claim 10, wherein
the first insulating film and the second insulating film have equal thicknesses.

12. The semiconductor memory according to claim 10, further comprising a metal film, formed on the semiconductor substrate, having a planar surface in the memory cell region and having a step portion corresponding to the alignment trench in the alignment mark region.

13. The semiconductor memory according to claim 10, further comprising:
a gate electrode arranged on the semiconductor substrate to traverse the active region between the element isolation trench and another element isolation trench;
a first charge storage portion arranged on a first side wall portion of the gate electrode to be opposed to the active region; and
a second charge storage portion arranged on a second side wall portion of the gate electrode opposite to the first side wall portion to be opposed to the active region.

14. A method of manufacturing a semiconductor memory, comprising the steps of:
forming an element isolation trench in a memory cell region of a semiconductor substrate;
forming an alignment trench in an alignment mark region of the semiconductor substrate;
embedding a first insulating film in the element isolation trench;
embedding a second insulating film in the alignment trench; and
digging down the first insulating film up to an intermediate portion of the element isolation trench in a depth direction and digging down the second insulating film up to an intermediate portion of the alignment trench in a depth direction by simultaneously etching the first insulating film and the second insulating film.

15. A method of manufacturing a semiconductor device, comprising:
a step of forming an element isolation trench for isolating an active region in a semiconductor substrate;
a step of forming a liner oxide film on an inner surface of the element isolation trench by thermal oxidation;
a heat treatment step of heat-treating the semiconductor substrate by arranging the semiconductor substrate in a nitrogen atmosphere after the formation of the liner oxide film;
a step of reducing the thickness of the liner oxide film; and
a step of embedding an insulator in the element isolation trench.

16. The method of manufacturing a semiconductor device according to claim 15, wherein
the step of reducing the thickness of the liner oxide film includes a step of etching a portion of not less than half the thickness of the liner oxide film in advance of the step of reducing the thickness of the liner oxide film.

17. The method of manufacturing a semiconductor device according to claim 15, wherein
the heat treatment step includes heat treatment at a temperature higher than a temperature in the thermal oxidation for forming the liner oxide film.

18. The method of manufacturing a semiconductor device according to claim 15, wherein
the heat treatment step includes a heat treatment step at a temperature of 1100° C. to 1200° C.

19. The method of manufacturing a semiconductor device according to claim 15, wherein
the thickness of the liner oxide film in advance of the step of reducing the thickness of the liner oxide film is not less than 8 nm.

20. A semiconductor device comprising:
a semiconductor substrate provided with an element isolation trench isolating an active region;
a liner oxide film having a thickness of not more than 50 Å formed on an inner surface of the element isolation trench; and
an insulator embedded in the element isolation trench.

21. A method of manufacturing a semiconductor device, comprising:
a step of forming a first gate layer;
a step of stacking a second gate layer on the first gate layer;
a step of etching the second gate layer into a prescribed gate pattern corresponding to a plurality of multilayer gates;
a step of etching the first gate layer into the prescribed gate pattern;
a step of forming sidewalls on side walls of a plurality of multilayer gates each including the first gate layer and the second gate layer etched into the gate pattern respectively;
a step of embedding an interlayer dielectric film between the sidewalls of adjacent ones of the multilayer gates; and
a side wall retracting step of retracting a side wall of the second gate layer beyond a side wall of the first gate layer before the formation of the sidewalls.

22. The method of manufacturing a semiconductor device according to claim 21, wherein
the second gate layer is made of tungsten silicide.

23. The method of manufacturing a semiconductor device according to claim 21, wherein
the first gate layer is made of polysilicon.

24. The method of manufacturing a semiconductor device according to claim 21, wherein
the side wall retracting step is carried out before the etching of the first gate layer.

25. The method of manufacturing a semiconductor device according to claim 21, wherein
the side wall retracting step is carried out after the etching of the first gate layer.

26. The method of manufacturing a semiconductor device according to claim 21, further including a step of nitriding a side wall surface of the second gate layer.

27. A semiconductor device comprising:
a first gate layer; and
a second gate layer, stacked on the first gate layer, containing nitrogen on a side wall surface formed to be flush with a side wall surface of the first gate.

28. The semiconductor device according to claim 27, further comprising:
sidewalls formed on the side wall surfaces of the first gate layer and the second gate layer; and
an interlayer dielectric film in contact with the sidewalls.
